(19) United States
(12) Patent Application Publication
(10) Pub. No.: US 2024/0071787 A1
(43) Pub. Date: Feb. 29, 2024

(54) SUBSTRATE HEAT-TREATING APPARATUS USING LASER LIGHT-EMITTING DEVICE

(71) Applicant: Viatron Co., Ltd., Gyeonggi-do (KR)

(72) Inventors: Hyoung June Kim, Seoul (KR); Byung Kuk Kim, Gyeonggi-do (KR); Wang Jun Park, Gyeonggi-do (KR); Oh Sung Kwon, Gyeonggi-do (KR); Tae Hyeong Kim, Gyeonggi-do (KR); Byeong Gyu Jeong, Gwangju (KR)

(21) Appl. No.: 18/270,148

(22) PCT Filed: Dec. 27, 2021
(86) PCT No.: PCT/KR2021/019965

§ 371 Date: Jun. 28, 2023

(30) Foreign Application Priority Data
Dec. 29, 2020 (KR) 10-2020-0185807

(51) Int. Cl. H01L 21/67; F27B 17/00; F27D 3/00; G01J 5/00

(52) U.S. Cl. CPC H01L 21/67115; F27B 17/0025; F27D 3/0084; G01J 5/0007

(57) ABSTRACT

The present disclosure discloses a substrate heat-treating apparatus including a process chamber in which a flat substrate to be heat treated is placed, the process chamber comprising a beam transmitting plate placed below the flat substrate and an infrared transmitting plate placed above the flat substrate; a beam irradiating module for irradiating a VCSEL beam having a single wavelength to a lower surface of the flat substrate through the beam transmitting plate; and an emissivity measuring configured to measure the laser beam reflected from the lower surface or an upper surface the flat substrate, thereby measuring the emissivity of the flat substrate.

### TECHNICAL FIELD

The present disclosure relates to a substrate heat-treating apparatus using a laser light-emitting device.

### BACKGROUND ART

A semiconductor wafer or a flat substrate such as a glass substrate for a flat panel display device may be manufactured into a semiconductor or flat panel display module by performing a heat treatment process such as an epitaxial process, a thin film crystallization process, an ion implantation process, or an activation process.

It is necessary that the flat substrate is kept at a constant temperature during a manufacturing process. In order to keep the temperature of the flat substrate constant, it is required to accurately measure the temperature of the flat substrate. The temperature of the flat substrate is generally measured using emissivity measured on the flat substrate. However, it is not easy to measure the emissivity of the flat substrate because it is influenced by the properties of the flat substrate, such as temperature, surface roughness, and shape of a surface pattern. In particular, the manufacturing process is proceeded at a relatively high temperature, so it is not easy to accurately measure the emissivity of the flat substrate.

Recently, the above manufacturing process requires a small temperature deviation and high temperature uniformity according to miniaturization of semiconductor technology. Therefore, the above heat treatment apparatus requires to accurately measure the temperature of the flat substrate.

### DISCLOSURE OF THE INVENTION

### Technical Problem

An object of the present disclosure is to provide a substrate heat-treating apparatus using a laser light-emitting device, which is able to measure emissivity of a flat substrate without using any separate light source.

### Technical Solution

A substrate heat-treating apparatus using a laser light-emitting device of the present disclosure includes a process chamber in which a flat substrate to be heat treated is placed, the process chamber comprising a beam transmitting plate placed below the flat substrate and an infrared transmitting plate placed above the flat substrate; a beam irradiating module for irradiating a VCSEL beam having a single wavelength to a lower surface of the flat substrate through the beam transmitting plate; and an emissivity measuring module configured to measure the laser beam reflected from the lower surface or an upper surface the flat substrate, thereby measuring the emissivity of the flat substrate.

In addition, the emissivity measuring module may be placed below the beam irradiating module to measure the laser beam reflected from the lower surface of the flat substrate, thereby measuring the emissivity of the flat substrate.

Also, the process chamber includes a side wall in which the flat substrate is seated, an outer housing in which the infrared transmitting plate and an upper plate are placed above the flat substrate in the side wall, and an inner housing placed below the flat substrate inside the outer housing and having an upper portion on which the beam irradiating plate is placed, wherein the beam irradiating module may be placed below the beam transmitting plate inside the inner housing.

Furthermore, the beam irradiating module has an emissivity measuring hole penetrating from an upper surface to a lower surface thereof, and the emissivity measuring module may be placed below the emissivity measuring hole.

In addition, the emissivity measuring module may include a power-meter placed below the emissivity measuring hole and configured to receive the laser beam, thereby measuring the emissivity.

Also, the emissivity measuring module may include an optical cable placed below the emissivity measuring hole to receive the laser beam, and a power-meter connected to the optical cable to measure the emissivity.

Furthermore, the beam irradiating module includes a laser light-emitting device, and the laser light-emitting device may include a surface light-emitting laser device or an edge light-emitting laser device.

In addition, the beam irradiating module includes a laser light-emitting device, and the laser light-emitting device may include a VCSEL device.

Also, the process chamber further includes a substrate support configured to support an outer side of the flat substrate, and the substrate heat-treating apparatus may further include a substrate rotating module configured to support and rotate the substrate support.

Furthermore, the substrate rotating module may include an inner rotating means having a ring shape in which N poles and S poles are alternately formed in a circumferential direction and being coupled to a lower portion of the substrate support within the chamber lower space, and an outer rotating means placed outside the outer housing to face the inner rotating means and configured to generate a magnetic force to rotate the inner rotating means.

### Advantageous Effects

The substrate heat-treating apparatus using the laser light-emitting device of the present disclosure may measure emissivity of a flat substrate using a VCSEL, which has a single wavelength and is used as a heat light source, without using a separate light source for measurement.

Also, since the substrate heat-treating apparatus using the laser light-emitting device of the present disclosure is placed parallel to the flat substrate below the flat substrate, the emissivity of the flat substrate can be measured more efficiently.

In addition, since the substrate heat-treating apparatus using the laser light-emitting device of the present disclosure does not use any separate light source for measuring emissivity, the structure of the apparatus can be simplified.

### BRIEF DESCRIPTION OF THE DRAWINGS

FIG. 1 is a view showing a configuration of a substrate heat-treating apparatus using a laser light-emitting device according to one embodiment of the present disclosure;

FIG. 2 is a partial perspective view of an irradiation module of FIG. 1;

FIG. 3 is a vertical cross-sectional view taken along the line A-A in FIG. 2; and

FIG. 4 is a partial enlarged view for section “B” in FIG. 1.

### BEST MODE FOR CARRYING OUT THE INVENTION

Hereinafter, a substrate heat-treating apparatus using a laser light-emitting device of the present disclosure is described in more detail with reference to through embodiments and accompanying drawings.

First, a configuration of a substrate heat-treating apparatus using a laser light-emitting device according to one embodiment of the present disclosure is described.

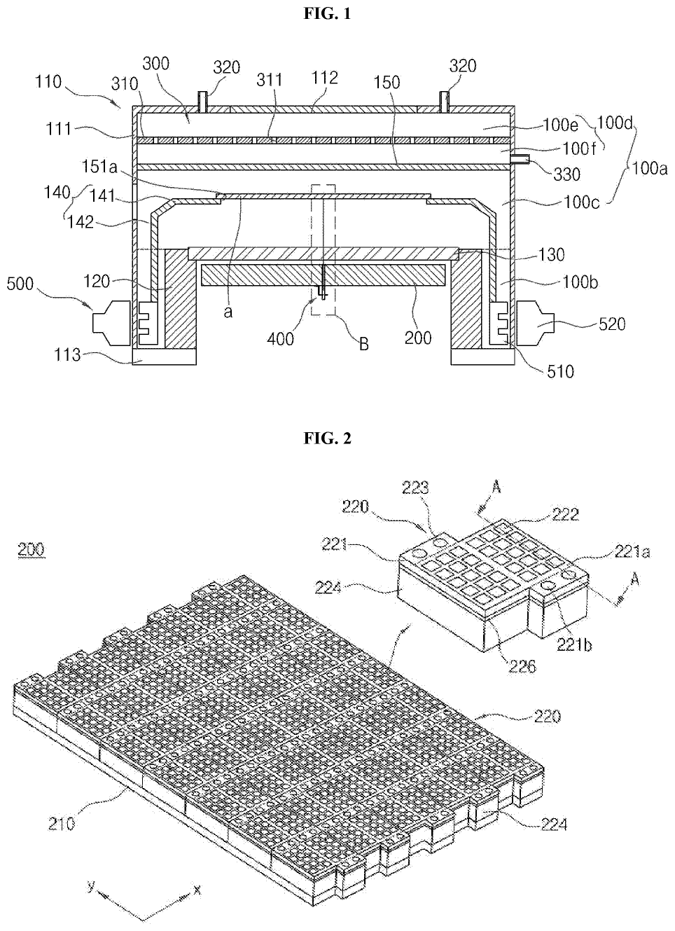

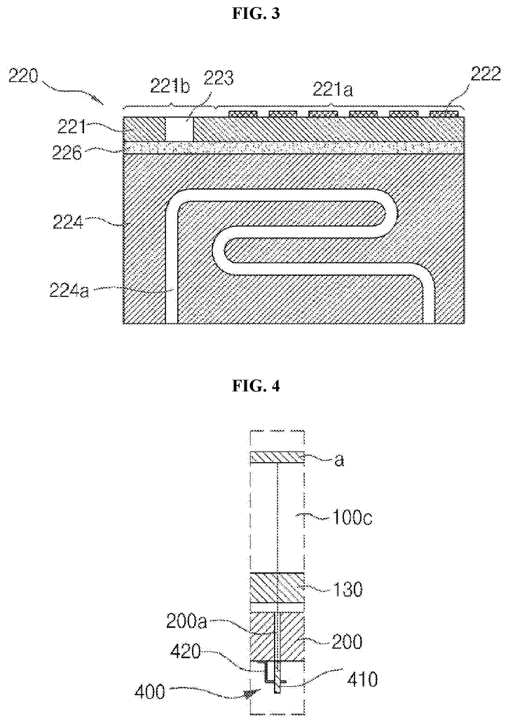

FIG. 1 is a view showing a configuration of a substrate heat-treating apparatus using a laser light-emitting device according to one embodiment of the present disclosure. FIG. 2 is a partial perspective view of an irradiation module of FIG. 1. FIG. 3 is a vertical cross-sectional view taken along the line A-A in FIG. 2. And, FIG. 4 is a partial enlarged view for section “B” in FIG. 1.

Referring to FIGS. 1 to 4, a substrate heat-treating apparatus 10 using a laser light-emitting device according to one embodiment of the present disclosure may include a process chamber 100, a beam irradiating module 200, a gas spraying module 300, an emissivity measuring module 400, and a substrate rotating module 500.

In the substrate heat-treating apparatus 10, a manufacturing process such as an epitaxial process, a crystallization process, an ion implantation process, or an activation process for a flat substrate a may be performed.

The substrate heat-treating apparatus 10 may employ the laser light-emitting device as a heat light source for heating the flat substrate a. The laser light-emitting device may be a surface light-emitting laser device or an edge light-emitting laser device. In addition, the laser light-emitting device may be a VCSEL device. The laser light-emitting device may be formed of a device that emits a laser beam with a single wavelength. For example, the laser light-emitting device may be a VCSEL device that emits a laser beam with a single wavelength of about 940 nm.

The substrate heat-treating apparatus 10 may irradiate the laser beam generated from the beam irradiating module 200, which includes a laser light-emitting device emitting the laser beam, to a lower surface of the flat substrate a to heat the flat substrate a. Here, the flat substrate a may be a semiconductor wafer or a glass substrate. Also, the flat substrate a may be a flexible substrate such as a resin film. In addition, the flat substrate a may include various elements or electrical conductive patterns formed on a surface of or inside the flat substrate.

The substrate heat-treating apparatus 10 utilizes the laser light-emitting device as a heat light source for heating the flat substrate a, and the laser light emitting device may irradiate the laser with single wave wavelength. For example, the laser light-emitting device may be formed of a VCSEL device that emits a laser beam with a single wavelength of about 940 nm. The substrate heat-treating apparatus 10 may measure emissivity of the flat substrate a using the laser beam of the laser light-emitting device employed as a heat light source without using a separate light source for measurement. For example, the substrate heat-treating apparatus 10 may measure reflectivity of the laser beam with single wavelength, which is irradiated from the VCSEL device to the lower surface of the flat substrate a and then reflected from the flat substrate, and calculate the emissivity.

In addition, since the substrate heat-treating apparatus 10 is placed below the flat substrate a and parallel to the flat substrate a, the emissivity of the flat substrate a can be measured more efficiently. Also, since the substrate heat-treating apparatus 10 does not utilize a separate light source for measuring the emissivity, the structure of the apparatus can be simplified.

Above the flat substrate a, in addition, the substrate heat-treating apparatus 10 may measure the laser beam, which is reflected from an upper surface of the flat substrate a, to measure the emissivity. At this time, the substrate heat-treating apparatus 10 may include a separate light source for measurement, which irradiates the laser beam to the upper surface of the flat substrate a. The light source for measurement may be formed to have a configuration which is the same as that of the irradiating module 200.

The process chamber 100 may include an outer housing 110, an inner housing 120, a beam transmitting plate 130, a substrate support 140, and an infrared transmitting plate 150. The process chamber 100 may provide a space in which the flat substrate a is accommodated and heat-treated. The flat substrate a may be supported by the substrate support 140 inside the process chamber 100. The process chamber 100 allows the laser beam generated from the beam irradiating module 200 placed at the outside to be irradiated to a lower surface of the flat substrate placed inside. The process chamber 100 allows the laser beam to pass through the beam transmitting plate 130 and to be then irradiated to the lower surface of the flat substrate a seated on the substrate support 140.

The outer housing 110 is formed in a hollow cylindrical shape and may include a side wall 111, an upper plate 112, and a lower plate 113. The outer housing 110 may be formed in an approximately cylindrical shape, a square column shape, a pentagonal column shape, or a hexagonal column shape. The outer housing 110 may be formed in a shape having a larger horizontal cross-sectional area than an area of the flat substrate a which is heat-treated therein.

The side wall 111 may be formed in a cylindrical shape, a square column shape, a pentagonal column shape, or a hexagonal column shape having a hollow inside. The side wall 111 provides a chamber upper space 100a in which a heat treatment is carried out. In addition, the side wall 111 provides a space in which parts of the beam irradiating module 200 and the substrate rotating module 500 are accommodated.

The upper plate 112 may be formed in a plate shape corresponding to a top planar shape of the side wall 111. The upper plate 112 is coupled to an upper end of the side wall 111 and may seal an upper side of the side wall 111.

The lower plate 113 corresponds to a bottom planar shape of the side wall 111, and a lower through hole 113 is formed on an inner side of the lower plate. The lower plate 113 may be formed as a circular ring or a square ring having a predetermined width. The lower plate 113 may be formed in various shapes according to a lower planar shape of a chamber lower space 100b. The lower plate 113 is coupled to a lower portion of the side wall 111 and shields a lower outer side of the side wall 111. A lower portion of the inner housing 120 described below may be coupled to an outer side of the through hole of the lower plate 113.

The inner housing 120 is formed in a hollow cylindrical shape, and may be formed in a cylindrical shape, a square column shape, a pentagonal column shape, or a hexagonal column shape. The inner housing 120 may be formed to have an outer diameter or an outer width smaller than an inner diameter or an inner width of the outer housing 110. Also, the inner housing 120 may be formed to have a height smaller than that the outer housing 110. In addition, the inner housing 120 may be formed to have a height by which an upper side thereof is placed below the flat substrate a seated inside the process chamber 100. In addition, the inner housing 120 may be formed to have a diameter or a width larger than a diameter or a width of the flat substrate a placed thereabove. Furthermore, the inner housing 120 may be formed to have a larger horizontal area than the flat substrate a. Therefore, the chamber upper space 100a in which the flat substrate a is seated is formed above the inner housing 120. That is, the chamber upper space 100a is formed above the inner housing 120 inside the outer housing 110 and provides a space in which the flat substrate a is seated. The flat substrate a may be placed in the chamber upper space 100a such that a lower surface of the region to be heat-treated is exposed when viewed from the lower portion of the inner housing 120.

Also, the inner housing 120 may be coupled such that a lower side of the inner housing 120 is placed at substantially the same height as a lower side of the outer housing 110. A lower end of the inner housing 120 may be coupled to an inner side of the lower plate 113. Thus, a space between an outer side of the inner housing 120 and an inner side of the outer housing 110 may be sealed by the lower plate 113. The chamber lower space 100b may be formed between an outer surface of the inner housing 120 and an inner surface of the outer housing 110. The chamber upper space 100a and the chamber lower space 100b may be shielded from the outside by the outer housing 110, the inner housing 120, and the lower plate 113 to be maintained in a vacuum or process gas atmosphere.

The beam transmitting plate 130 is coupled to an upper portion of the inner housing 120 and may be placed below the flat substrate a. The beam transmitting plate 130 may be formed of a transparent plate, such as quartz or glass, through which a laser beam is transmitted. The beam transmitting plate 130 allows the laser beam to be transmitted and then irradiated to the lower surface of the flat substrate a. More specifically, the beam transmitting plate 130 allows, in the inner housing 120, the laser beam incident through a lower surface thereof to be irradiated to the lower surface of the flat substrate a. The beam transmitting plate 130 may be formed to have an area larger than that of the flat substrate a. For example, the beam transmitting plate 130 may be formed to have a diameter or a width greater than a diameter or a width of the flat substrate a. The beam transmitting plate 130 may preferably be formed to have a diameter or a width greater than 1.1 times a diameter or a width of the flat substrate a. In this case, the beam transmitting plate 130 enables the laser beam to be irradiated to the entire lower surface of the flat substrate a.

The substrate support 140 may include an upper support 141 and a connection support 142. The substrate support 140 may be placed above the inner housing 120 to support a lower outer side of the flat substrate a such that the lower surface of the flat substrate a is exposed. In addition, the substrate support 140 may extend into the chamber lower space 100b to be coupled with the substrate rotating module 500. The substrate support 140 may rotate the flat substrate a in response to an action of the substrate rotating module 500.

The upper support 141 may have a substrate exposing hole 141a formed in an inner side thereof, thereby formed in a ring shape having a predetermined width. The upper support 141 may support a lower outer side of the flat substrate a while exposing the lower surface of the flat substrate a. The upper support 141 may be formed to have a diameter or a width greater than a diameter or a width of the flat substrate a.

The substrate exposing hole 141a may be formed by penetrating upper and lower surfaces at a central portion of the upper support 141. The substrate exposing hole 141a may be formed to have a predetermined area such that a region, requiring heat treatment, of the lower surface of the flat substrate a may be entirely exposed.

The connection support 142 is formed in an approximately cylindrical shape with opened upper and lower sides, and may be formed in a shape corresponding to the shape of the inner housing 120. For example, the lower support may be formed in a cylindrical shape corresponding to the inner housing when the inner housing 120 is formed in a cylindrical shape. The connection support 142 may be placed over the chamber upper space 100a and the chamber lower space 100b. An upper portion of the connection support 142 may be coupled to an outer side of the upper support 141, and a lower portion may be extended into the chamber lower space 100b to be coupled to the substrate rotating module 500. Accordingly, the connection support 142 may rotate the upper support 151 and the flat substrate a while being rotated by the substrate rotating module 500.

The infrared transmitting plate 150 may be formed in a plate shape corresponding to a planar shape of the upper portion of the side wall 111. The infrared transmitting plate 150 may be formed of transparent quartz. The infrared transmitting plate 150 may be placed between the upper plate 112 and the substrate support 140 at an upper portion of the side wall 111. The infrared transmitting plate 150 may divide the chamber upper space 100a of the outer housing 110 into a heat treatment space 100c and a cooling gas space 100d. The heat treatment space 100c is a space in which the flat substrate a is placed and heat treatment is carried out. The cooling gas space 100d is a space into which a cooling gas for cooling the infrared transmitting plate 150 flows, and is placed above the heat treatment space 100c. The infrared transmitting plate 150 may be placed above the flat substrate a to allow a lower surface thereof to face the upper surface of the flat substrate a. On the other hand, the infrared transmitting plate 150 forms the upper surface of the outer housing 110, and the side wall 111 and the upper plate 112 on the upper part of the infrared transmitting plate 150 may be separately formed to be coupled to the upper portion of the infrared transmitting plate 150.

The infrared transmitting plate 150 may be formed of transparent quartz to allow radiant energy generated from the flat substrate a during a heat treatment process to be transmitted to the outside. In particular, the infrared transmitting plate 150 may transmit radiant energy of a wavelength including infrared ray to the outside. In addition, the infrared transmitting plate 150 is maintained at a temperature of 400° C. or less, and preferably may be maintained at a temperature of 300 to 400° C. Since the infrared transmitting plate 150 is maintained at a temperature of 300 to 400° C., a chemical deposition caused by process gas may be prevented, thereby preventing an increase in emissivity due to deposition. Here, the process gas may be varied depending on the type of heat treatment process. For example, gases such as SiH₄, SiH₂Cl₂, SiHCl₃, or SiCl₄ may be used as a process gas in the epitaxial process.

When a temperature of the cooling gas is 400° C. or less, chemical vapor deposition may be significantly reduced. In addition, since emissivity of the infrared transmitting plate 150 is not increased according to the number of heat treatment processes, it is possible to reduce difference in process temperature between the flat substrates a on which the process is proceeded.

The beam irradiating module 200 may include a device array plate 210 and sub-irradiation modules 220. The beam irradiating module 200 may be placed at an outer lower portion of the process chamber 100 to irradiate the laser beam, which has single wavelength, to the lower surface of the flat substrate a through the beam transmitting plate 130. The beam irradiating module 200 may irradiate the laser beam having single wavelength of 940 nm to heat the flat substrate a. The beam irradiating module 200 may be placed below the beam transmitting plate 130 within the inner housing 120.

The beam irradiating module 200 includes an emissivity measuring hole 200a penetrating from an upper surface to a lower surface of a region thereof corresponding to the lower surface of the flat substrate a. The emissivity measuring hole 200a may be preferably formed in a region corresponding to a center of the flat substrate a. The emissivity measuring hole 200a may provide a path in which the emissivity measuring module 400 measure the emissivity in a non-contact manner.

In the beam irradiating module 200, the plurality of sub-irradiation modules 220 may be arranged on an upper surface of the device array plate 210 in a grid form. Referring to FIG. 2, the sub-irradiation modules 220 may be arranged on the upper surface of the device array plate 210 in x-direction and y-direction to be arranged in a grid shape.

The device array plate 210 may be formed in a plate shape having a predetermined area and a thickness. The device array plate 210 may be preferably formed to correspond to the shape and area of the flat substrate a. The device array plate 210 may be formed of a thermally conductive ceramic material or metallic material. The device array plate 210 may function to radiate heat generated from the laser light-emitting device.

The sub-irradiation module 220 may include a device substrate 221, laser light-emitting devices 222, an electrode terminal 223, and a cooling block 224. The plurality of the sub-irradiation modules 220 may be arranged and placed on the device array plate 210 in a grid direction. The sub-irradiation module 220 may be arranged on a region, which is required for irradiating a laser beam to an irradiation region of the flat substrate a, on a surface of the device array plate 210. The device substrate 221 may be coupled to the cooling block 224 by a separate adhesive layer 226.

The sub-irradiation module 220 is formed by arranging the plurality of laser light-emitting devices 222 in the x-axial direction and the y-axial direction. Although not specifically illustrated, the sub-irradiation module 220 may include a light-emitting frame (not shown) for securing the laser light-emitting device 222 and a power line (not shown) for supplying power to the laser light-emitting device 222. The sub-irradiation module 220 may be formed such that the same power is applied to all of the laser light-emitting devices 222. In addition, the sub-irradiation module 220 may be formed such that different powers are applied to the laser light-emitting devices 222, respectively.

The device substrate 221 may be formed of a general substrate used for mounting electronic devices. The device substrate 221 may be divided into a device region 221a on which the laser light-emitting device 222 is mounted and a terminal region 221b on which the electrode terminal is mounted. On the device region 221a, the plurality of laser light-emitting devices 222 may be arranged and mounted in a grid shape. The terminal region 221b is placed to be adjacent to the device region 221a, and the plurality of electrode terminals may be mounted on this terminal region.

The laser light-emitting device 222 may be formed of various light-emitting devices irradiating the laser beam. For example, the light-emitting device 222 may be formed of a surface light-emitting device or an edge light-emitting device. In addition, the laser light-emitting device 222 may be formed of a VCSEL device. The VCSEL device may irradiate the laser beam with a single wavelength of 940 nm. The VCSEL device may be formed to have a quadrangular shape, preferably a square shape or a rectangular shape in which the ratio of width to length does not exceed 1:2. The VCSEL device is manufactured as a cubic-shaped chip, and a high-power laser beam is oscillated from one surface thereof. Since the laser light-emitting device oscillates a high-power laser beam, compared to a conventional halogen lamp, this device may increase a temperature rise rate of the flat substrate a and has also a relatively long lifespan.

In the device region 221a, the plurality of the laser light-emitting devices 222 may be arranged on an upper surface of the device substrate 221 in the x-direction and the y-direction to be arranged in a gird shape. An appropriate number of the laser light-emitting devices 222 may be formed at appropriate intervals according to the area of the device region 221a and the amount of energy of a laser beam irradiated to the flat substrate a. In addition, the laser light-emitting devices 222 may be placed at an interval by which uniform energy may be irradiated when a laser beam emitted from one laser light-emitting device overlaps a laser beam of the adjacent laser light-emitting device 222. At this time, the laser light-emitting devices 222 may be placed such that sides of the adjacent laser light-emitting devices 222 are in contact with each other, so there is no separation distance therebetween.

The plurality of the electrode terminals 223 may be formed in the terminal region 221b of the device substrate 221. The electrode terminals 223 include a + terminal and a − terminal, and may be electrically connected to the laser light-emitting device 222. Although not specifically illustrated, the electrode terminal 223 may be electrically connected to the laser light-emitting device 222 in various ways. The electrode terminal 223 may supply power required for driving the laser light-emitting device 222.

The cooling block 224 may be formed to have a planar shape corresponding to a planar shape of the device substrate 221, and a predetermined height. The cooling block 224 may be formed of a thermally conductive ceramic material or metallic material. The cooling block 224 may be coupled to a lower surface of the device substrate 221 by a separate adhesive layer. The cooling block 224 may radiate heat generated from the laser light-emitting device 222 mounted on a surface of the device substrate 221 downward. Therefore, the cooling block 224 may cool the device substrate 221 and the laser light-emitting device 222.

A cooling passage 224a through which cooling water flows may be formed in the cooling block 224. The cooling passage 224a may have an inlet port and an outlet port formed on a lower surface of the cooling block, and may be formed in the cooling block 224 as various types of flow passages.

The gas spraying module 300 may include a gas spraying plate 310, a gas supply pipe 320 and a gas discharging pipe 330. The gas spraying module 300 may spray cooling gas to the upper surface of the infrared transmitting plate 150 to cool the infrared transmitting plate 150. The cooling gas may be nitrogen gas, argon gas or compressed cooling air.

The gas spraying plate 310 is formed in a plate shape and may have gas spraying holes 311 penetrating from an upper surface to a lower surface thereof. The gas spraying plate 310 may be placed parallel to the infrared transmitting plate 150 between the upper plate 112 and the infrared transmitting plate 150 at an upper portion of the outer housing 110. The gas spraying plate 310 may divide a gas spraying space 100d into an upper gas space 100e and a lower gas space 100f.

By penetrating the gas spraying plate 310 from the upper surface to the lower surface, the gas spraying hole 311 is formed. That is, the gas spraying hole 311 may communicate the upper gas space 100e and the lower gas space 100f with each other. The gas spraying hole 311 may spray the cooling gas, which flows into the gas spraying space 100d from the outside, to the lower gas space 100f.

The plurality of gas spraying holes 311 may be formed in the gas spraying plate 310 to be entirely spaced apart from each other. The gas spraying holes 311 may more uniformly spray the cooling gas supplied into the upper gas space 100e into the lower gas space 100f. Therefore, the gas spraying plate 310 may more uniformly cool the infrared transmitting plate 150 placed there below.

The gas supply pipe 320 is formed in a tubular shape with both opened sides, and is coupled to the upper plate 112 of the outer housing 110 to communicate the inside of the outer housing 110 with the outside. That is, the gas supply pipe 320 passes through the upper plate 112 from the outside to enter the upper gas space 100e. The plurality of gas supply pipes 320 may be formed according to the area of the upper plate 112. The gas supply pipe 320 may be connected to an external cooling gas supply device to be supplied with the cooling gas. In addition, the gas supply pipe 320 may be connected to the gas circulation cooling module to be supplied with the cooling gas.

The gas discharging pipe 330 is formed in a tubular shape with both opened sides, and may be coupled to the sidewall 111 of the outer housing 110 to communicate the lower gas space 100f with the outside. That is, the gas discharging pipe 330 passes through the side wall 111 from the outside to enter the lower gas space 100f. The plurality of gas discharging pipes 330 may be formed according to the area of the upper plate 112. The gas discharging pipe 330 may discharge the cooling gas flowing into the lower gas space 100f to the outside. In addition, the gas discharging pipe 330 may be connected to the gas circulation cooling module to discharge the cooling gas.

The emissivity measuring module 400 may include a power-meter 410 and a power-meter support 420. The emissivity measuring module 400 may measure the laser beam with a single wavelength of the laser light-emitting device 222 which is reflected from the lower surface of the flat substrate a, through the emissivity measuring hole 200a of the beam irradiating module 200 to determine the emissivity. The emissivity measuring module 400 measures the reflectivity of the laser beam with a single wavelength, which is irradiated from the laser light-emitting device 222 used as the heat light source onto the lower surface of the flat substrate a and then reflected, to measure the emissivity of the flat substrate a. Therefore, the emissivity measuring module 400 does not require a separate light source for measuring reflectivity. In addition, since the emissivity measuring module 400 measures the reflectivity of the flat substrate a in a state in which only a laser beam with single wavelength is irradiated, it can measure the reflectivity more accurately.

In addition, the emissivity measuring module 400 may measure the reflectivity of the laser beam reflected from the upper surface of the flat substrate a to measure the emissivity of the flat substrate a. At this time, the emissivity measuring module 400 may include a separate light source for measuring emissivity, which irradiates a laser beam with a single wavelength onto the upper surface of the flat substrate a. The light source for measuring the emissivity may be configured to have the same structure as that of the beam irradiating module 200. That is, the light source for measuring the emissivity may be formed of one VCSEL element.

The power-meter 410 may measure the emissivity of the flat substrate a in a non-contact manner. At a lower portion of the beam irradiating module 200, the power meter 410 is placed below the emissivity measuring hole 200. In addition, although not specifically illustrated, the power-meter 410 is connected to a separate optical cable and may be placed outside the process chamber 100. At this time, the optical cable may be placed below the emissivity measuring 200a to receive the laser beam with a single wavelength reflected from the flat substrate. In addition, the power-meter 410 may be placed above the flat substrate a. Above the flat substrate a, the power-meter 410 may measure the emissivity of the flat substrate (a).

At a lower portion of the beam irradiating module 200, the power-meter support 420 may secure the power-meter 410 to a lower portion of the emissivity measuring hole 200a. The power-meter support 420 may be formed in various structures capable of supporting the power-meter 410.

The substrate rotating module 500 may include an inner rotating means 510 and an outer rotating means 520. The substrate rotating module 500 may rotate the substrate support 140 in a horizontal direction in a non-contact manner. More specifically, the inner rotating means 510 may be coupled to a lower portion of the substrate support 140 in the chamber lower space 100b of the process chamber 100. In addition, the outer rotating means 520 may be placed to face the inner rotating means 510 at the outside of the process chamber 100. The outer rotating means 520 may rotate the inner rotating means 510 in a non-contact manner using a magnetic force.

The inner rotation means 510 may be formed to have the same structure as a rotor of a motor. For example, the inner rotating means 510 may be formed as a magnet structure, which is formed in a ring shape as a whole and has N poles and S poles alternately arranged in a circumferential direction. The inner rotating means 510 may be coupled to the lower portion of the substrate support 140, that is, the connection support 142. At this time, the inner rotating means 510 may be placed to be spaced upward apart from an upper portion of the lower plate 113. Meanwhile, although not specifically illustrated, the inner rotating means 510 may be supported by a separate support means to prevent vibration from being generated or to ensure that it can be rotated smoothly, during rotation thereof. For example, a lower portion of the inner rotating means 510 may be supported by a support bearing or a roller.

The outer rotating means 520 may be formed to have the same structure as a stator of a motor. For example, the outer rotating means 520 may include an iron core formed in a shape of ring and a conducting wire wound around the iron core. The outer rotating means 520 may rotate the inner rotating means 510 with a magnetic force generated by power supplied to the conducting wire. The outer rotating means 520 may be placed outside the outer housing 110 so as to face the inner rotating means 310 with respect to the outer housing 110. In other words, the outer rotating means 520 may be placed outside the outer housing with the respect to the outer housing 110 at the same height as the inner rotating means 510.

In order to help those skilled in the art to understand, the most preferred embodiment is selected from the various implementable embodiments of the present disclosure, and is set forth in the present specification, and the technical spirit of the present disclosure is not necessarily restricted or limited only by these embodiments, and various changes, additions, and modification are possible without departing from the technical spirit of the present disclosure, and implementations of other equivalent embodiments are possible.

1. A substrate heat-treating apparatus comprising:
a process chamber in which a flat substrate to be heat treated is placed, the process chamber comprising a beam transmitting plate placed below the flat substrate and an infrared transmitting plate placed above the flat substrate;
a beam irradiating module for irradiating a VCSEL beam having a single wavelength to a lower surface of the flat substrate through the beam transmitting plate; and
an emissivity measuring module configured to measure the laser beam reflected from the lower surface or an upper surface the flat substrate, thereby measuring the emissivity of the flat substrate.

2. The substrate heat-treating apparatus of claim 1, wherein the emissivity measuring module is placed below the beam irradiating module to measure the laser beam reflected from the lower surface of the flat substrate, thereby measuring the emissivity of the flat substrate.

3. The substrate heat-treating apparatus of claim 2, wherein the process chamber comprises;
a side wall in which the flat substrate is seated,
an outer housing in which the infrared transmitting plate and an upper plate are placed above the flat substrate in the side wall, and
an inner housing placed below the flat substrate inside the outer housing and having an upper portion on which the beam irradiating plate is placed,
wherein the beam irradiating module is placed below the beam transmitting plate inside the inner housing.

4. The substrate heat-treating apparatus of claim 3, wherein the beam irradiating module comprises an emissivity measuring hole penetrating from an upper surface to a lower surface thereof, and the emissivity measuring module is placed below the emissivity measuring hole.

5. The substrate heat-treating apparatus of claim 2, wherein the emissivity measuring module comprises a power-meter placed below the emissivity measuring hole and configured to receive the laser beam, thereby measuring the emissivity.

6. The substrate heat-treating apparatus of claim 2, wherein the emissivity measuring module comprises an optical cable placed below the emissivity measuring hole to receive the laser beam, and a power-meter connected to the optical cable to measure the emissivity.

7. The substrate heat-treating apparatus of claim 2, wherein the beam irradiating module comprises a laser light-emitting device, and the laser light-emitting device comprises a surface light-emitting laser device or an edge light-emitting laser device.

8. The substrate heat-treating apparatus of claim 2, wherein the beam irradiating module comprises a laser light-emitting device, and the laser light-emitting device comprises a VCSEL device.

9. The substrate heat-treating apparatus of claim 2, wherein the process chamber further comprises a substrate support configured to support an outer side of the flat substrate, and the substrate heat-treating apparatus further comprises a substrate rotating module configured to support and rotate the substrate support.

10. The substrate heat-treating apparatus of claim 2, wherein the substrate rotating module comprises;
an inner rotating means having a ring shape in which N poles and S poles are alternately formed in a circumferential direction and being coupled to a lower portion of the substrate support within the chamber lower space, and
an outer rotating means placed outside the outer housing to face the inner rotating means and configured to generate a magnetic force to rotate the inner rotating means.

11. The substrate heat-treating apparatus of claim 1, wherein the process chamber comprises;
a side wall in which the flat substrate is seated,
an outer housing in which the infrared transmitting plate and an upper plate are placed above the flat substrate in the side wall, and
an inner housing placed below the flat substrate inside the outer housing and having an upper portion on which the beam irradiating plate is placed,
wherein the beam irradiating module is placed below the beam transmitting plate inside the inner housing.

12. The substrate heat-treating apparatus of claim 1, wherein the beam irradiating module comprises an emissivity measuring hole penetrating from an upper surface to a lower surface thereof, and the emissivity measuring module is placed below the emissivity measuring hole.

13. The substrate heat-treating apparatus of claim 12, wherein the emissivity measuring module comprises a power-meter placed below the emissivity measuring hole and configured to receive the laser beam, thereby measuring the emissivity.

14. The substrate heat-treating apparatus of claim 12, wherein the emissivity measuring module comprises an optical cable placed below the emissivity measuring hole to receive the laser beam, and a power-meter connected to the optical cable to measure the emissivity.

15. The substrate heat-treating apparatus of claim 1, wherein the beam irradiating module comprises a laser light-emitting device, and the laser light-emitting device comprises a surface light-emitting laser device or an edge light-emitting laser device.

16. The substrate heat-treating apparatus of claim 1, wherein the beam irradiating module comprises a laser light-emitting device, and the laser light-emitting device comprises a VCSEL device.

17. The substrate heat-treating apparatus of claim 1, wherein the process chamber further comprises a substrate support configured to support an outer side of the flat substrate, and the substrate heat-treating apparatus further comprises a substrate rotating module configured to support and rotate the substrate support.

18. The substrate heat-treating apparatus of claim 17, wherein the substrate rotating module comprises;
an inner rotating means having a ring shape in which N poles and S poles are alternately formed in a circumferential direction and being coupled to a lower portion of the substrate support within the chamber lower space, and
an outer rotating means placed outside the outer housing to face the inner rotating means and configured to generate a magnetic force to rotate the inner rotating means.
